(19) United States
(12) Patent Application Publication
(10) Pub. No.: US 2025/0228041 A1
(43) Pub. Date: Jul. 10, 2025

(54) MICRO-NETWORK INTERCONNECTED NANOSTRUCTURES

(71) Applicant: The Regents of the University of Michigan, Ann Arbor, MI (US)

(72) Inventors: Ishtiaque Navid, Ann Arbor, MI (US); Ayush Pandey, Ann Arbor, MI (US); Zetian Mi, Ann Arbor, MI (US)

(21) Appl. No.: 18/703,499

(22) PCT Filed: Oct. 24, 2022
(86) PCT No.: PCT/US2022/047559

§ 371 Date: Apr. 22, 2024

Related U.S. Application Data
(60) Provisional application No. 63/270,708, filed on Oct. 22, 2021.

(51) Int. Cl. H10H 20/819; H10H 20/01; H10H 20/815; H10H 20/825

(52) U.S. Cl. CPC H10H 20/819; H10H 20/01335; H10H 20/815; H10H 20/825

(57) ABSTRACT

A device includes a substrate, a buffer layer supported by the substrate, and a plurality of nanostructures supported by the substrate. Each nanostructure of the plurality of nanostructures is shaped as a wall extending outward from the substrate. The walls of the plurality of nanostructures are interconnected to define a set of voids, each void of the set of voids extending outward from the substrate. The buffer layer is disposed between the substrate and each nanostructure of the plurality of nanostructures

### CROSS-REFERENCE TO RELATED APPLICATION

This application claims the benefit of U.S. provisional application entitled “Micro-Network Interconnected Nanostructures,” filed Oct. 22, 2021, and assigned Ser. No. 63/270,708, the entire disclosure of which is hereby expressly incorporated by reference.

### BACKGROUND OF THE DISCLOSURE

### Field of the Disclosure

The disclosure relates generally to nanostructure-based optoelectronic and other devices.

### Brief Description of Related Technology

In the past two decades, semiconducting nanostructures, e.g., nanowires, have been extensively studied for applications in optoelectronics, including light-emitting diode (LED) devices, lasers, solar cells, and photodetectors. To date, however, it has remained a daunting challenge to achieve high efficiency nanoscale optoelectronic devices. It is generally believed that the underlying challenge is directly related to the enhanced nonradiative surface recombination, due to the large surface area. As an example, while broad area InGaN blue quantum well LEDs can exhibit external quantum efficiency (EQE) greater than 80%, the efficiency decreases by at least one to two orders of magnitude when the device dimensions are reduced to micron- or nano-scale, due to the dominant nonradiative surface recombination. The efficiency cliff of optoelectronics, i.e., drastically reduced efficiency when the device sizes are shrunk to the micro- or nano-scale, becomes even more severe for III-nitride light emitters in the deep visible (green to red), due to the large lattice mismatch (about 11%) between GaN and InN, which not only leads to the formation of extensive defects, disorders, and dislocations, but also significantly reduces the electron-hole wavefunction overlap due to piezo-electric field induced polarization.

Semiconducting nanowires for applications in optoelectronics have commonly had lateral dimensions on the order of 100 nm, or larger. Glas et al. analyzed the critical dimensions for the plastic relaxation of semiconducting nanowires, showing that the critical layer thickness depends strongly on the nanowire diameter. Schematically shown in FIG. 1 is the estimated critical layer thickness plotted versus the nanowire diameter for a heterostructure with lattice mismatch of about 4%, corresponding approximately to In_{0.32}Ga_{0.68}N grown on GaN emitting in the green spectrum. The critical layer thickness is about 1 nm for conventional planar heterostructures (shaded grey region in FIG. 1), which is increased to about 3 nm for InGaN nanowire structures with diameters of about 100 nm (shaded blue region in FIG. 1). It is therefore seen that the epitaxy of conventional InGaN/GaN nanowire arrays inevitably leads to the formation of extensive defects. The resulting dominant nonradiative (surface) recombination is evident by the extremely short carrier lifetime (sub nanosecond) commonly measured for nanowire structures at room temperature, compared to a few nanoseconds of their planar counterparts, which explains largely the low efficiency of conventional nanowire optoelectronic devices. The critical layer thickness, however, can be potentially increased to an indefinitely large value if the lateral dimensions are further reduced to the deep-nano regime (less than 40 nm), shown as the shaded green region in FIG. 1. Indeed, recent studies suggested that strain relaxation was most efficient in InGaN/GaN nanostructures with lateral dimensions less than 40 nm, consistent with the calculation by Glas et al., Efficient strain relaxation of InGaN nanostructures not only drastically reduces defect densities but also significantly enhances the exciton binding energy due to the increased electron-hole wavefunction overlap. A nearly 100-fold enhancement in the exciton oscillator strength was measured in InGaN nanostructures with lateral dimensions less than 40 nm. It is therefore envisioned that the efficiency cliff of nanoscale optoelectronic devices can be potentially mitigated by developing semiconducting heterostructures in the deep-nano regime. To date, however, the controlled synthesis and optoelectronic properties of such ultrasmall InGaN nanostructures has been insufficiently explored.

### SUMMARY OF THE DISCLOSURE

In accordance with one aspect of the disclosure, a device includes a substrate, a buffer layer supported by the substrate, and a plurality of nanostructures supported by the substrate, each nanostructure of the plurality of nanostructures being shaped as a wall extending outward from the substrate. The walls of the plurality of nanostructures are interconnected to define a set of voids, each void of the set of voids extending outward from the substrate. The buffer layer is disposed between the substrate and each nanostructure of the plurality of nanostructures.

In accordance with another aspect of the disclosure, a method of fabricating a device includes implementing a first epitaxial growth procedure to grow a buffer layer on a substrate, the first epitaxial growth procedure having a duration such that the buffer layer includes a plurality of interconnected islands that define voids in the buffer layer, and implementing a second epitaxial growth procedure to grow a plurality of nanostructures on the plurality of interconnected islands of the buffer layer.

In accordance with yet another aspect of the disclosure, a device includes a substrate, a buffer layer supported by the substrate, and a plurality of nanostructures supported by the substrate, each nanostructure of the plurality of nanostructures including a III-nitride semiconductor material. The plurality of nanostructures extend outward from the substrate and are vertically aligned. The buffer layer is disposed between the substrate and each nanostructure of the plurality of nanostructures. Each nanostructure of the plurality of nanostructures has a lateral dimension sufficiently small so as to promote charge carrier interaction to form excitons.

In accordance with still another aspect of the disclosure, a device includes a substrate, a buffer layer supported by the substrate, and a plurality of nanostructures supported by the substrate, each nanostructure of the plurality of nanostructures including a III-nitride semiconductor material. The plurality of nanostructures extend outward from the substrate and are vertically aligned. The buffer layer is disposed between the substrate and each nanostructure of the plurality of nanostructures. Each nanostructure of the plurality of nanostructures has a lateral dimension sufficiently small so as to establish strain relaxation within the III-nitride semiconductor material.

In connection with any one of the aforementioned aspects, the devices and/or methods described herein may alternatively or additionally include or involve any combination of one or more of the following aspects or features. The buffer layer includes a plurality of interconnected islands that define voids in the buffer layer. The buffer layer includes AlN. The buffer layer has a thickness of about 5 nm or less. Each nanostructure of the plurality of nanostructures includes a GaN layer and an InGaN layer supported by the GaN layer. Each nanostructure of the plurality of nanostructures has a lateral thickness less than about 40 nm. Each nanostructure of the plurality of nanostructures has a lateral thickness at least an order of magnitude lower than heights of the plurality of nanostructures. Each nanostructure of the plurality of nanostructures is doped p-type. The second epitaxial growth procedure is implemented in a nitrogen-rich environment. Implementing a second epitaxial growth procedure includes growing a GaN layer on the buffer layer, and growing an InGaN layer on the GaN layer. The second epitaxial growth procedure is implemented without a metal catalyst. The first epitaxial growth procedure is configured such that the buffer layer has a thickness of about 5 nm or less. The lateral dimension is less than about 40 nm. Each nanostructure of the plurality of nanostructures is shaped as a wall extending outward from the substrate such that the lateral dimension corresponds with a thickness of the wall. Each nanostructure of the plurality of nanostructures is doped p-type.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a graphical plot of the critical thickness variation of a lattice-mismatched heterostructure as a function of the lateral dimension, in which the curve represents the variation of the critical layer thickness for a misfitting layer (misfit of about 4%) growing on top of a nanowire as a function of the nanowire radius (adapted from Glas et al.), and via which it is seen that, in the deep-nano regime, the critical layer thickness can be infinitely large.

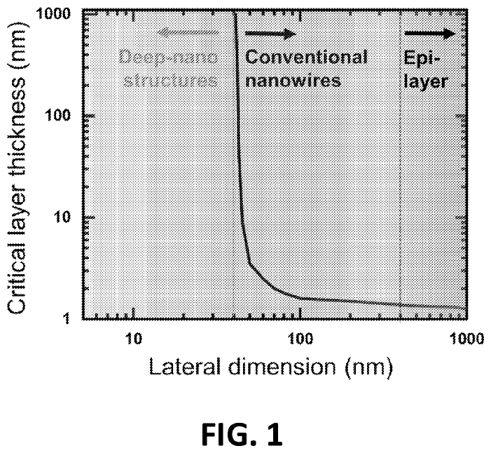

FIG. 2 depicts (a) a schematic representation of a GaN micro-network nanostructure grown on Si substrate with AlN buffer layer in accordance with one example, and (b-d) SEM images of GaN nanostructures grown on Si, including (b) an SEM image of nanowire arrays formed on Si in the absence of any AlN buffer layer, (c) an SEM image of a mixture of nanowires and micro-network nanostructures are formed on Si with the use of an about a single monolayer thick AlN buffer layer, and (d) an SEM image of GaN micro-network nanostructures formed on Si with the use of an about 8 nm thick AlN buffer layer in accordance with one example.

FIG. 3 depicts (a) an SEM image of as-grown InGaN micro-network nanostructures on Si (111) substrate at 45° tilt angle (with the inset depicting a schematic of the layer structure in accordance with one example), (b) a top view SEM image of as-grown InGaN micro-network nanostructures, (c) high-angle annular dark field (HAADF) STEM images of cross-sectional InGaN micro-network nanostructures with energy-dispersive X-ray (EDS) elemental mapping of Ga and In atoms, (d) selected area electron diffraction (SAED) across about 2.5 μm of micro-network nanostructure in cross section, in which imaging regions corresponding to each SAED pattern are marked by circular apertures with matching colors and single-crystallinity is maintained over the entire range (about 2.5 μm) with only 0.5° crystal rotation over a distance of 1.75 μm, and (e) an atomic resolution HAADF-STEM image that confirms that the specimen is highly crystalline and consistent with the InGaN [100] lattice plane.

FIG. 4 depicts graphical plots of (a) normalized room-temperature photoluminescence (PL) spectra for InGaN micro-network nanostructures, showing tunable emission in the entire visible spectrum, (b) photoluminescence spectra of the InGaN micro-network sample and conventional InGaN nanowire structures with similar surface area, showing nearly two orders of magnitude enhancement of the luminescence emission, and (c) variations of the integrated PL intensity with excitation power for InGaN micro-network and nanowire structures measured at room temperature.

FIG. 5 depicts graphical plots of (a) TRPL for InGaN micro-network nanostructures measured at different excitation powers, (b) carrier lifetime versus excitation power density of the InGaN micro-network nanostructures and InGaN nanowires at room temperature, (c) EQE variation as a function of power density for InGaN micro-network nanostructures and InGaN nanowires, showing nearly two orders of magnitude enhancement of luminescence emission efficiency of micro-network nanostructures, compared to conventional nanowires.

FIG. 6 depicts (a) a 45° tilt SEM image of as-grown p-type doped InGaN micro-network nanostructure, (b) a schematic representation of the different layers in the micro-network nanostructure, (c) a HAADF-STEM image of InGaN micro-network nanostructure cross-section, (d) an atomic-resolution HAADF-STEM image of InGaN micro-network confirming its high crystallinity, (e) a high-resolution HAADF-STEM that shows the Rh/Cr₂O₃ core-shell structures and Co₃O₄ nanoparticles deposited on InGaN micro-network.

FIG. 7 depicts (a, b) schematic and graphical representations of the half-reactions of O₂ and H₂ production with respect to irradiation time under full arc illumination with AM1.5 filter, with the reaction processes depicted in the insets, respectively, (c) a graphical representation of H₂ and O₂ evolution versus irradiation time in the overall photocatalytic water splitting process under irradiation with AM1.5 filter, and (d) a schematic illustration of the redox reaction of the overall photocatalytic water splitting process on the Rh/Cr₂O₃ coreshell and CO₃O₄ nanoparticle decorated InGaN micro-network nanostructure.

FIG. 8 depicts (a) a graphical plot of STH conversion efficiency variation for different Mg-doped InGaN micro-network nanostructures under illumination with AM1.5 filter, and (b, c) schematic representations of the qualitative energy band diagram for low-Mg doped InGaN micro-network showing severe downward band bending and optimum-Mg doped InGaN micro-network with approximately flat band condition near the surface.

FIG. 9 depicts graphical representations of (a) TRPL for p-InGaN micro-network nanostructure for different Mg cell temperatures, with the corresponding carrier lifetime versus Mg cell temperature is shown in the inset, and (b) carrier lifetime and STH conversion efficiency variations (solid lines are fitted) with respect to Mg cell temperature.

FIG. 10 depicts a flow diagram of a method of fabricating a device in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices having a micro-network of interconnected nanostructures are described. The nanostructures may be sized in the deep-nano regime. In some cases, the nanostructures are GaN-based structures. The dimensions and other characteristics of the nanostructures break the efficiency bottleneck presented by conventional nanoscale optoelectronic devices. Methods for fabricating such devices are also described.

In one aspect, the challenges associated with conventional InGaN nanowires can be fundamentally addressed by developing InGaN micro-network nanostructures in the deep nano-regime. As described herein, the lateral dimension (e.g., wall thickness) of the nanostructures may be sufficiently low (e.g., less than 100 nm) so as to lead to (1) strain relaxation and (2) exciton formation. The lateral dimensions of the nanostructures are so small that strain relaxation becomes very efficient. Nonradiative charge carrier recombination rates accordingly decrease, which, in optoelectronic applications, leads to more efficient emissions. The small lateral dimensions also lower the polarization field within the nanostructures, which promotes the formation of excitons.

The disclosed methods may include the molecular beam epitaxy of InGaN micro-networks grown directly on Si wafer. In one aspect, the growth of the nanostructures may be enabled by a very thin buffer layer (e.g., AlN buffer layer). The buffer layer may be grown in nitrogen-rich conditions such that the vertical growth rate exceeds that of the lateral growth rate, which thereby leads to void formation along the substrate.

The nanostructures of the disclosed devices may exhibit lateral dimensions as small as 2-5 nm. The nanostructures of the self-assembled micro-networks are monocrystalline, despite the complexity of the nanostructures.

In optoelectronic cases, by controlling the growth conditions, the emission wavelengths can be tuned in the entire visible spectrum. For InGaN micro-network nanostructures emitting in the green wavelength, the emission intensity is nearly two orders of magnitude stronger than that of conventional InGaN nanowire arrays, due to the significantly reduced defect formation and enhanced exciton oscillator strength. Detailed time-resolved photoluminescence spectroscopy shows that the carrier lifetime is about 6 ns at room temperature. The surface recombination velocity is estimated to be about 150 cm/s, which is nearly one to two orders of magnitude lower than conventional InGaN nanowire or epilayer structures. The disclosed methods and devices may thus support a new generation of nanostructures useful for high efficiency optoelectronic devices in the deep visible and other wavelengths.

Although described in connection with optoelectronic, the disclosed methods and devices may be applied to a wide variety of applications. For instance, the interconnected nanostructures of the micro-networks described herein may be useful in various catalytic applications. The micro-networks may thus be incorporated into electrodes and other electrochemical devices. Although described below in connection with examples involving GaN and InGaN nanostructures, the disclosed methods and devices may use other III-nitride materials. For instance, other III-nitride semiconductor materials may be used, such as AlGaN. Although described below in connection with examples having an AlN buffer layer, additional or alternative materials may be used, including, for instance, SiC, BN, AlGaN and ScAlN. Although described below in connection with examples having a Si substrate, additional or alternative materials may be used, including, for instance, various metals, sapphire, and SiC. Although described below in connection with examples having a GaN template layer, additional or alternative materials may be used, including, for instance, various metals.

Examples of Ga(In)N micro-network nanostructures were grown on Si substrate utilizing a Veeco Gen II molecular beam epitaxy (MBE) system equipped with a radio-frequency plasma-assisted nitrogen source. Previous studies have shown that, when grown under nitrogen-rich conditions, Ga(In)N nanowires can be readily formed on a Si wafer, which are promoted by the initial nucleation of GaN islands on the substrate and their preferential growth along the c-axis driven by energy minimization.

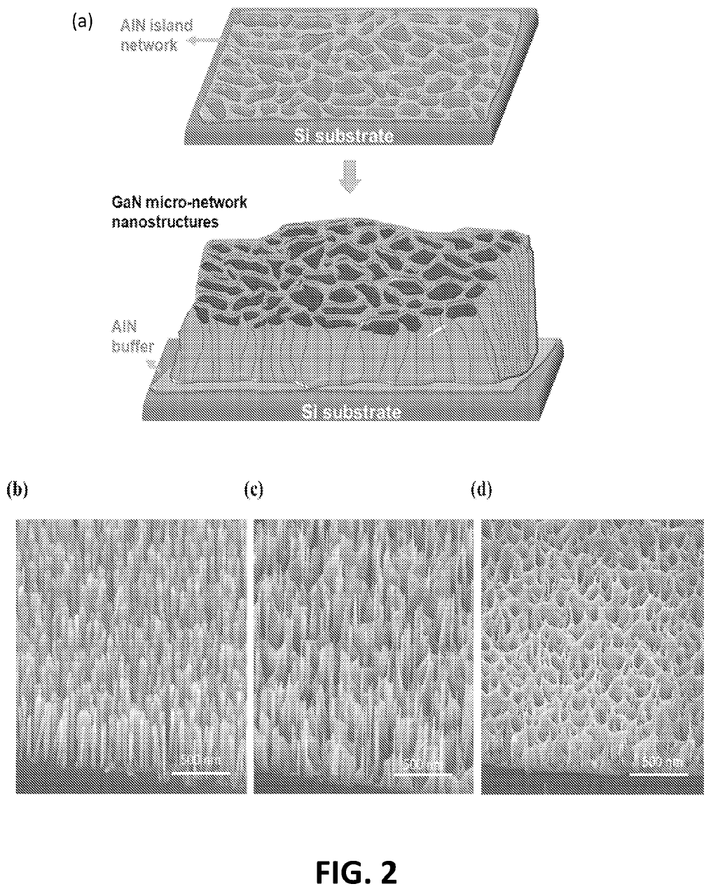

However, in contrast to conventional nanowire epitaxy, the disclosed methods may include or use an ultrathin (e.g., approximately sub-nanometer to a few nanometer) AlN buffer layer, schematically shown in FIG. 2, part (a), to precisely control the formation of crystalline GaN micro-network nanostructures with lateral dimensions in the deep-nano regime, i.e., nearly one order of magnitude reduction compared to conventional nanowires grown by MBE.

An AlN buffer layer has been used for the epitaxy of III-nitrides on Si wafer, but few studies have paid attention to the effect of the initial AlN nucleation on the subsequent growth and epitaxy process. In the disclosed methods and devices, the thickness of the AlN layer was varied from sub-nm to about 8 nm. Due to the large lattice mismatch (about 17%), the epitaxy of a thin AlN layer is described by the Volmer-Weber growth mode, which is characterized by the presence of nanoscale AlN islands, instead of smooth epilayers, on the Si substrate. In addition, due to the small Al adatom migration length, these islands are connected, with the presence of extensive voids, forming a nanoscale micro-network-like structure on the Si substrate. It is found that the micro-network of AlN islands plays a critical role on the subsequent epitaxy of GaN nanostructures. Impingent Ga adatoms migrate through the opening voids. Different from nanowire epitaxy, however, the nucleation sites of GaN are pre-determined by the AlN island micro-networks. The nanoscale AlN islands serve as the nucleation sites and promote the coherent epitaxy of GaN, whereas no epitaxy takes place in the opening voids, thereby leading to the formation of a unique GaN micro-network nanostructures. The crystalline AlN island micro-networks further promote the formation of single crystalline InGaN micro-network nanostructures, as described below.

As schematically shown in FIG. 2, part (a), the micro-network may include a plurality of nanostructures that are interconnected to define a set of voids extending outward from the substrate. Each nanostructure may be shaped as a wall extending outward from the substrate. Each nanostructure may have a lateral dimension (e.g., thickness) less than about 40 nm. In some cases, the lateral dimension may be as low as about 4 nm to about 5 nm.

FIG. 2, parts (b)-(d), are scanning electron microscopy (SEM) images of GaN nanostructures grown on Si with (or without) the use of various AlN buffer layers under otherwise identical conditions. Shown in FIG. 2, part (b), without the use of any AlN buffer layer, conventional GaN nanowire arrays are formed directly on Si wafer, and have diameters (or lateral widths) of about 100 nm. The introduction of a thin (about 1 monolayer) AlN buffer layer, however, leads to the mixture of GaN nanowires and micro-networks. The evolution from nanowires to micro-network nanostructures can be clearly observed with gradual increase of the AlN buffer layer thickness. Further increase of the AlN layer thickness suppresses the formation of nanowires and results in GaN micro-network nanostructures.

The AlN buffer layer may influence the morphology and dimension of GaN micro-networks. With increasing AlN buffer layer thickness, there is a gradual decrease of the lateral widths of the micro-network structures to as small as about 5 nm. However, further increasing AlN buffer layer thicknesses beyond about 5-10 nm leads to the formation of micro-network structures with larger lateral widths and eventual coalescence. The AlN buffer layer impacts the initial as well as the complete growth morphology of the GaN nanostructures.

The effect of growth parameters on the formation and properties of the GaN micro-network nanostructures on an AlN buffer layer with a nominal thickness of about 5 nm was also studied via a number of examples. It is observed that the lateral widths of the micro-network nanostructures show a decreasing trend with increasing N₂ flow rate and/or increasing growth temperature.

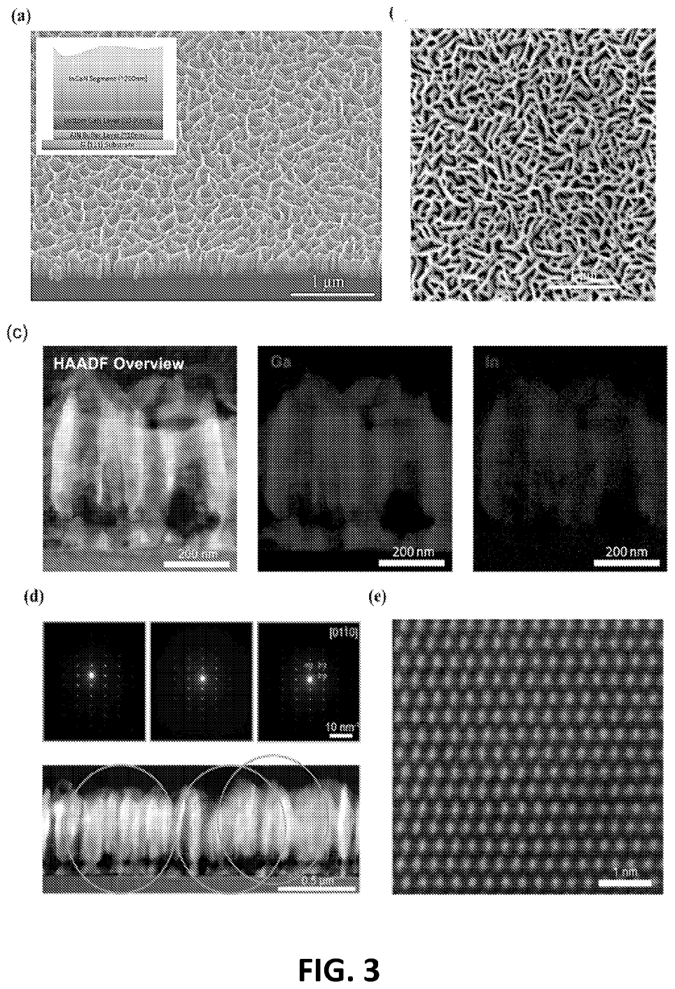

As shown in FIG. 3, part (a), the GaN micro-network nanostructures may then be utilized as a template for the epitaxy of InGaN nanostructures. Each resulting nanostructure may therefore include an InGaN segment supported by (e.g., in contact with) a GaN layer or segment, which, in turn, is supported by (e.g., in contact with) the AlN buffer layer, which, in turn, is supported by (e.g., in contact with) the substrate (e.g., silicon substrate).

N-rich growth conditions may be used to promote the epitaxy of InGaN preferentially along the c-axis while suppressing lateral growth. Examples of InGaN micro-network nanostructures were realized, as shown in FIG. 3, parts (a) and (b). Based on the SEM image analysis, it is observed that the average pore size of the structure is about 0.01 square micron with a range of circularity averaging 0.63. Electron microscopy characterization of the InGaN micro-network nanostructure reveals successful large-scale growth of an In-rich InGaN structure with no phase segregation and with high crystallinity. The epitaxial growth of an In-rich InGaN segment on top of a bottom GaN layer is further confirmed through STEM imaging and simultaneous chemical mapping of the micro-network nanostructure structure (FIG. 3, part (c)). Indium distribution in the InGaN segment is unconfined and homogeneous, which suggests large-scale incorporation of In-rich crystal across the entire micro-network nanostructure.

As indicated by the sharp diffraction peaks in selected area electron diffraction (SAED) patterns (FIG. 3, part (d)), the InGaN micro-network nanostructures are single crystal and share a common crystallographic axis. The stark crystallinity of the InGaN micro-network defies initial expectations from the complex mesoscale morphology. Single crystallinity is maintained across microns of material, as shown by the circular aperture selecting the entire micro-network nanostructure in cross-section. Across about 1.75 μm of the micro-network laterally, there is only less than 0.5 degree rotation of the crystal axis. Crystallinity of the InGaN structure is further verified at atomic resolution with high-angle annular dark field (HAADF) STEM. The atomic structure in FIG. 3, part (e) matches that of the [100] lattice plane of InGaN crystal. The unique single crystalline nature of such complex nanostructure arrays is directly related to the coherent epitaxy of GaN on single crystalline AlN island micro-networks. From the atomic resolution HAADF STEM images, there are no discernible dislocations over a 15 nm×15 nm range; however, dislocations could exist beyond the range indicated. The micro-network lateral thickness (e.g., wall thicknesses) vary from as small as a few nanometers to tens of nanometers, while the height (e.g., wall height) is about 200 nm. One or more of the growth parameters may be varied to control the formation and properties of the InGaN micro-network nanostructures.

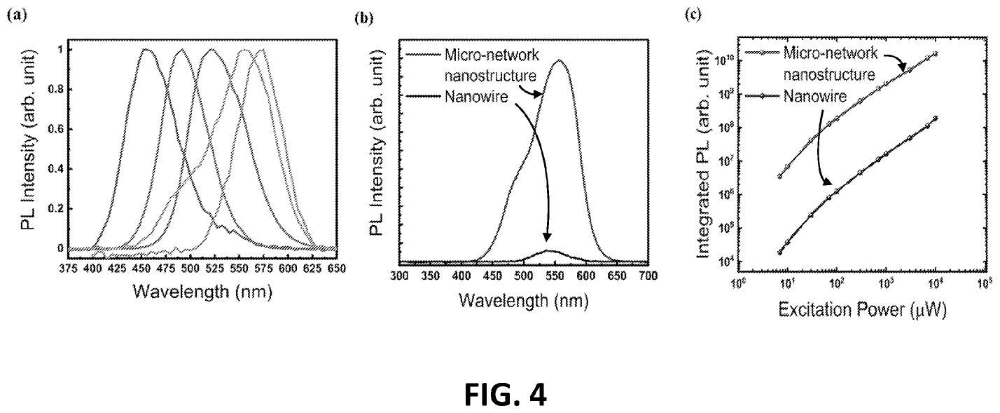

InGaN micro-network nanostructures grown on Si may be tuned or configured to exhibit emission across nearly the entire visible spectrum. Shown in FIG. 4, part (a), are the normalized photoluminescence spectra measured at room temperature for InGaN micro-networks with various indium incorporation. It is seen that the emission wavelengths can be controllably tuned from blue to green, yellow, orange, and red.

FIG. 4, part (b), shows the room temperature photoluminescence spectra of the InGaN micro-network and that of a conventional InGaN nanowire structure with nearly identical surface area. It is seen that InGaN micro-network nanostructures exhibit nearly two orders of magnitude enhancement in the luminescence emission.

Shown in FIG. 4, part (c), the extremely bright photoluminescence emission of InGaN micro-network nanostructures, compared to conventional nanowires, is further confirmed over a broad range of excitation power. It is worth noting that, given their nearly identical surface area, the drastically enhanced luminescence intensity cannot be solely explained by variations in the light extraction efficiency. Instead, the ultra-bright photoluminescence intensity of the InGaN micro-network nanostructures can be attributed to the significantly reduced nonradiative surface recombination and enhanced exciton oscillator strength in such nanoscale structures.

Strain relaxation of InGaN/GaN is most significant in nanostructures with lateral dimensions of about 40 nm, or less, thereby leading to drastically reduced nonradiative (surface) recombination. Moreover, efficient strain relaxation leads to significantly reduced piezo-electric polarization fields and therefore enhanced electron-hole wavefunction overlap. As such, the exciton binding energy increases drastically with reducing lateral dimensions of InGaN nanostructures. Exciton binding energy in the range of 70-100 meV has been calculated for InGaN nanowall structures with lateral dimensions less than 40 nm, which is nearly five to ten times larger than that in InGaN bulk. Previous studies further suggested that the exciton oscillator strength of InGaN nanostructures with such small dimensions could be enhanced by nearly 100-fold, compared to quantum well or conventional nanowire structures, thereby leading to significantly enhanced quantum efficiency and emission intensity.

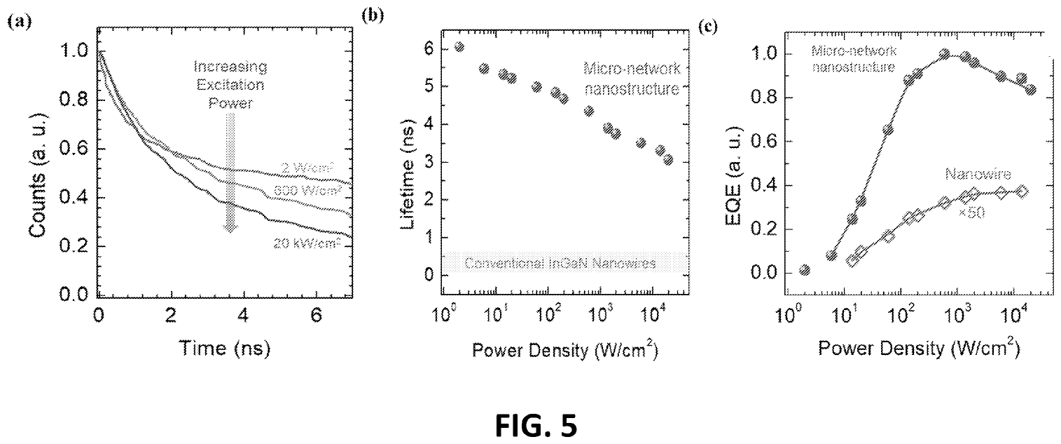

Optical properties and carrier dynamics of InGaN micro-network nanostructures were further studied utilizing time-resolved femtosecond laser spectroscopy. The samples were excited with the 400 nm output from the second harmonic of a 80 MHz/70 fs Ti:sapphire laser, focused to a spot of 16 μm diameter. The photoluminescence transient was analyzed using a 0.75 m monochromator and a high-speed single photon counter. The photoluminescence transients for the InGaN micro-network sample measured at different excitation power densities from 2 W/cm² to 20 kW/cm² are shown in FIG. 5, part (a). The transients were fitted using a standard stretched exponential decay, and plotted in FIG. 5, part (b), where a relatively long lifetime of over 5 ns was measured for the InGaN micro-network nanostructures at low excitation powers. Such relatively long carrier lifetime is comparable to that of high quality InGaN quantum well structures despite the large surface area, suggesting that nonradiative surface recombination plays a negligible role in the carrier recombination. This observation is also consistent with the extremely bright photoluminescence emission measured at room temperature and can be well explained by the robust excitonic emission and reduced SRH recombination, which would have the dominant effect on carrier lifetime at low carrier densities. At higher excitation, a decrease in lifetime is observed, which can be attributed to the enhanced radiative recombination and, to some extent, higher order carrier loss terms such as Auger recombination and carrier delocalization. For comparison, significantly shorter carrier lifetime in the range of 0.2-0.5 ns have been commonly measured for conventional InGaN nanowire arrays, limited by surface recombination, shown in FIG. 5, part (b).

Excitation power dependent measurements were also performed on the InGaN micro-network nanostructures as well as some spontaneous InGaN nanowire samples utilizing the same laser source as described above. The photoluminescence signals were analyzed using a 0.75 m monochromator and detected with a UV-enhanced PMT. The relative external quantum efficiency (EQE) at different excitation powers is plotted in FIG. 5, part (c) for both samples. It is seen that the EQE of InGaN micro-network nanostructures is nearly two orders of magnitude higher than that of InGaN nanowire samples, which is consistent with the measurements shown in FIG. 4. At higher excitation powers, a clear efficiency droop is observed for the micro-network nanostructures, which is similar to that of conventional high efficiency broad area InGaN light emitters. Efficiency droop, however, is not seen for the InGaN nanowire sample, due to the dominant nonradiative SRH recombination. To further analyze the data, the generation rate was estimated for different excitation intensities.

Under very low excitation conditions, the carrier lifetime is primarily limited by nonradiative surface recombination for nearly strain and defect-free InGaN nanostructures. If neglecting the contribution of bulk recombination to the carrier lifetime, the nonradiative surface recombination lifetime is estimated about 6 ns for micro-network nanostructures, which is nearly one order of magnitude higher than that of conventional nanowire structures (commonly measured in the range of 0.2-0.5 ns at room temperature). Therefore, an upper bound of the surface recombination velocity (S) can be estimated from the following equation:

$$S = \frac{d}{4 {τ}_{PL}}$$

where d is the lateral width of the nanostructures and τ_{PL} is the carrier lifetime determined from the TRPL measurements under low excitation conditions. For the micro-network nanostructures with lateral widths of about 30 nm, the surface recombination velocity is calculated to be about 150 cm/s. For InGaN nanowire samples, based on the commonly measured carrier lifetime of about 0.3 ns and nanowire diameters of about 100 nm, the surface recombination velocity is estimated to be about 10,000 cm/s. It is seen that the strain relaxed InGaN micro-network nanostructures of the disclosed devices exhibit a surface recombination velocity that is nearly two orders of magnitude smaller than conventional nanowires. The drastically reduced surface recombination, together with the enhanced electron-hole wavefunction overlap and exciton oscillator strength, can therefore explain the extremely bright luminescence emission of InGaN micro-network nanostructures.

Described above is the epitaxy and characterization of InGaN structures in the deep-nano regime, with lateral dimensions as small as a few nm. These strain-relaxed nanostructures exhibit drastically reduced defect formation, negligible nonradiative surface recombination, as well as significantly enhanced exciton oscillator strength. Compared to conventional nanowire structures with similar surface area, the surface recombination velocity of such deep-nano structures is reduced by nearly two orders of magnitude, which is evidenced by the extremely bright luminescence emission as well as the long carrier lifetime measured at room temperature. The disclosed methods and devices may accordingly include next generation semiconducting nanostructures that break the efficiency bottleneck of nanoscale optoelectronic devices.

The disclosed methods may include the epitaxy of micro-network nanostructures performed under nitrogen-rich conditions. The epitaxy of the examples described above used a Veeco Gen II radio-frequency plasma-assisted molecular beam epitaxy (MBE) growth system on a Si (111) substrate. The Si substrate was cleaned with acetone and methanol and subsequently dipped into 10% buffered hydrofluoric acid prior to loading in order to eliminate the native oxides. No external metal catalyst was involved for the growth of the micro-network under the nitrogen-rich environment. The AlN buffer layer growth parameters include a substrate temperature of 810° C., Al beam equivalent pressure (BEP) of 2×10⁻⁸ torr, and N₂ flow rate of 1 sccm. The GaN growth parameters include a substrate temperature 680° C., Ga BEP of 5×10⁻⁸ torr, and N₂ flow rate 1.5 sccm. Ga BEP of 5×10⁻⁸ torr, In BEP of 4.5×10⁻⁸ torr, and 1.5 sccm nitrogen flow rate were used for the InGaN micro-network layer. The initial thin AlN buffer layer was directly grown on Si (111) substrate for up to 5 mins. Then, the bottom GaN layer was grown on top of buffer AlN segment for 1 hour. The top InGaN layer was subsequently grown for 2 hours on top of the GaN layer. The parameters of the epitaxial growth procedures may vary in other cases.

Described above are devices that address the challenge presented by conventional nanoscale optoelectronic devices, which generally exhibit low efficiency, due to dominant nonradiative surface recombination. In one aspect, the challenge is addressed by exploiting semiconducting structures in the deep-nano regime. The epitaxy-based fabrication, and structural and optical characteristics, of GaN-based micro-network nanostructures grown on Si wafer have been described. These complex nanostructures have lateral dimensions as small as a few nanometers. Detailed scanning transmission electron microscopy images show that the self-assembled micro-network nanostructures are monocrystalline and largely free of dislocations, despite the porous nature of the micro-network. The disclosed devices having such micro-network nanostructures exhibit ultrabright emission in the visible spectrum. Compared to conventional InGaN nanowire structures with similar surface area, the surface recombination velocity of such deep-nano structures is reduced by nearly two orders of magnitude, which is evidenced by the extremely bright luminescence emission as well as the long carrier lifetime measured under low excitation conditions. The disclosed devices and methods are accordingly useful in next generation high efficiency nanoscale optoelectronic and other devices.

Examples of GaN-based micro-network nanostructures incorporated into photocatalytic solar water splitting and other photocatalytic applications are now described. The GaN-based micro-network nanostructures may be composed of, or otherwise include, p-type doped InGaN. As described below, the photocatalytic water splitting reaction may occur on a non-polar sidewall of the InGaN micro-network nanostructures.

Water splitting with solar energy has become one of the most promising techniques for hydrogen production with renewable energy resources. Photocatalytic water splitting involves only water and essentially no energy input, such as external applied bias, other than sunlight. To date, many of the high efficiency water splitting devices are based on 11-arsenide and III-phosphide compound semiconductors. However, those devices suffer from poor stability caused by photocorrosion in acidic or alkaline medium under operating conditions. Recent studies have showed that among the III-nitride materials, InGaN is the only semiconductor with a tunable bandgap within the entire solar spectrum and capable of straddling the redox potentials of water under ultraviolet, visible and infrared irradiation. As such, InGaN is a useful semiconductor material for high efficiency photocatalytic water splitting process. Furthermore, GaN-based nanostructures are also reported to be chemically very stable against photocorrosion. Kibria et al. reported a solar-to-hydrogen (STH) conversion efficiency of about 1.8% using InGaN nanowires. Overall water splitting utilizing InGaN and visible light responsive photocatalysts has also been achieved.

Semiconductor nanowires has been used in optoelectronic device applications, but there are several challenges in realizing high efficiency nanoscale photonic devices due to non-radiative surface recombination resulting from defects, disorders and dislocations. As described above, Glas et al. analyzed the critical thickness dependence on the lateral dimension of lattice-mismatched heterostructures. The critical layer thickness can indefinitely be increased with the lateral dimension of the heterostructure below 40 nm. Other studies also report the most efficient strain relaxation in InGaN/GaN nanostructures have a lateral dimension less than 40 nm. Efficient strain relaxation in the InGaN nanostructures results in a significant reduction in defect densities and substantial increase in exciton binding energy, leading to superior optoelectronic properties compared to conventional InGaN nanowires. Furthermore, networks of GaN-based nanowalls are reported to have several orders of magnitude higher electron mobility than that in a bulk structure. The electron mobility was found to increase as the wall width decreases, which is presumably attributed to the electron transport through the edge states on the top edges of the nanowall.

The examples described below apply wall-shaped network nanostructures in the context of artificial photosynthesis (e.g., solar water splitting). Such nanostructures are found to be useful in such contexts, as, for instance, photogenerated charge carrier transfer and extraction play roles in these processes.

Surface band bending is useful for photoelectrochemical water splitting because the redox reactions take place at separate electrodes. On the other hand, it may be minimized for photocatalytic water splitting for balanced, stable and efficient oxidation and reduction reactions. The surface band bending on photocatalyst nanostructures resulting from Fermi-level pinning creates an energy barrier for the charge carriers to diffuse to the photocatalyst-liquid interface, resulting in low efficiency.

Example devices are described below that implement the photocatalytic water splitting reaction on the non-polar sidewall of InGaN micro-network nanostructures. In the non-polar Ga(In)N surfaces, the occupied states are located beyond the energy bandgap and as such Fermi-level pinning does not take place. Due to the presence of defects and impurity incorporation, downward band bending is commonly found on p-type Ga(In)N surfaces. In general, p-type Ga(In)N nanostructures have weakly n-type or intrinsic surfaces, the Fermi level of which is located slightly above the water photoelectrochemical potential and so its downward band bending can be reduced in equilibrium with water. This makes it possible to have more balanced and efficient redox reactions by tuning the p-type doping concentration, i.e., the Fermi level on the nanostructure surfaces. Moreover, p-type photocatalysts provide free holes, and as such can significantly enhance the water splitting efficiency because the water oxidation is usually the rate limiting step in the overall process. In this context, the p-type Mg doping on the InGaN micro-network has been useful in its impact on the photocatalytic water splitting as well as the charge carrier dynamics.

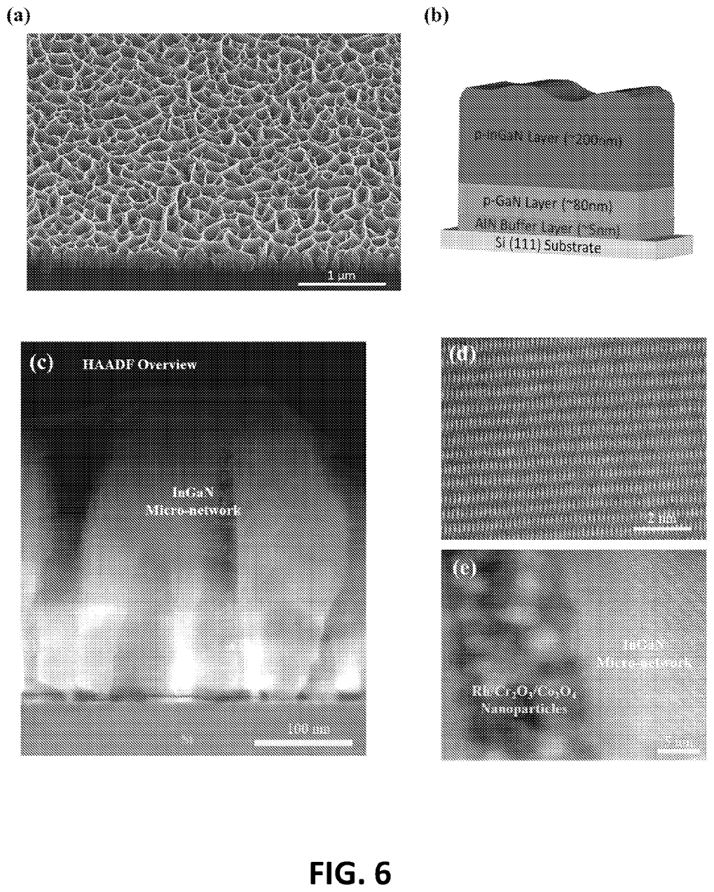

FIG. 6, part (a), depicts scanning electron microscope (SEM) images of an example of p-InGaN micro-networks grown on a Si (111) substrate. The micro-network structure is vertically aligned on the Si wafer with average lateral dimensions of about 50 nm and lengths falling in a range from about 280 to about 300 nm. As shown in the schematic of FIG. 6, part (b), initially a thin layer (e.g., about 5 nm) of AlN buffer layer was directly grown on the Si substrate. This thin layer of AlN has been employed for the controlled growth of GaN micro-network structure with very small lateral dimensions. Owing to a considerable amount of lattice mismatch (about 17%), the growth of thin AlN layer on Si (111) takes place as nanoscale islands rather than continuous smooth epilayers. Since Al adatoms have small migration length, these islands form a connected network with voids. Subsequently, these AlN nanoscale islands play the role of nucleation sites for coherent GaN epitaxy with no epitaxy in the extensive voids. This results in the formation of the GaN micro-network morphology. The InGaN micro-network nanostructure layer (e.g., about 200 nm) was subsequently grown on this GaN micro-network template (e.g., about 80 nm) as schematically shown in FIG. 6, part (b). In this example, Mg doped p-type InGaN micro-network growths were carried out on Si substrate in nitrogen rich condition with a Veeco Gen II radio-frequency plasma-assisted molecular beam epitaxy (MBE) system. Other aspects of the growth conditions are described above in connection with the previous nanostructure examples.

Large-scale epitaxial growth of In-rich and highly crystalline InGaN micro-network structure without any phase segregation was indicated by electron microscopy characterization. The high-angle annular dark field (HAADF)-scanning transmission electron microscopy (STEM) imaging in FIG. 6, part (c), along with energy-dispersive X-ray (EDS) elemental mapping of the micro-network structure, revealed the epitaxy of a top InGaN layer on a bottom GaN segment. The atomic-resolution HAADF-STEM in FIG. 6, part (d), substantiates the high crystalline nature of the InGaN micro-network nanostructure, which shows clear lattice fringes. The coherent epitaxial growth of GaN and subsequently InGaN on top of monocrystalline islands of AlN micro-network results in the formation of such single crystal nanostructure arrays.

In this example, Rh/Cr₂O₃ core-shell and Co₃O₄ nanoparticles were photodeposited on the InGaN micro-network nanostructure, which act as cocatalysts for promoting hydrogen and oxygen evolution, respectively. FIG. 6, part (e), depicts high resolution HAADF-STEM images of the Rh/Cr₂O₃ coreshell and Co₃O₄ nanoparticles loaded InGaN micro-network structure. EDS elemental mapping further confirms the successful photodeposition of these cocatalysts on the lateral surface of the InGaN micro-network nanostructure.

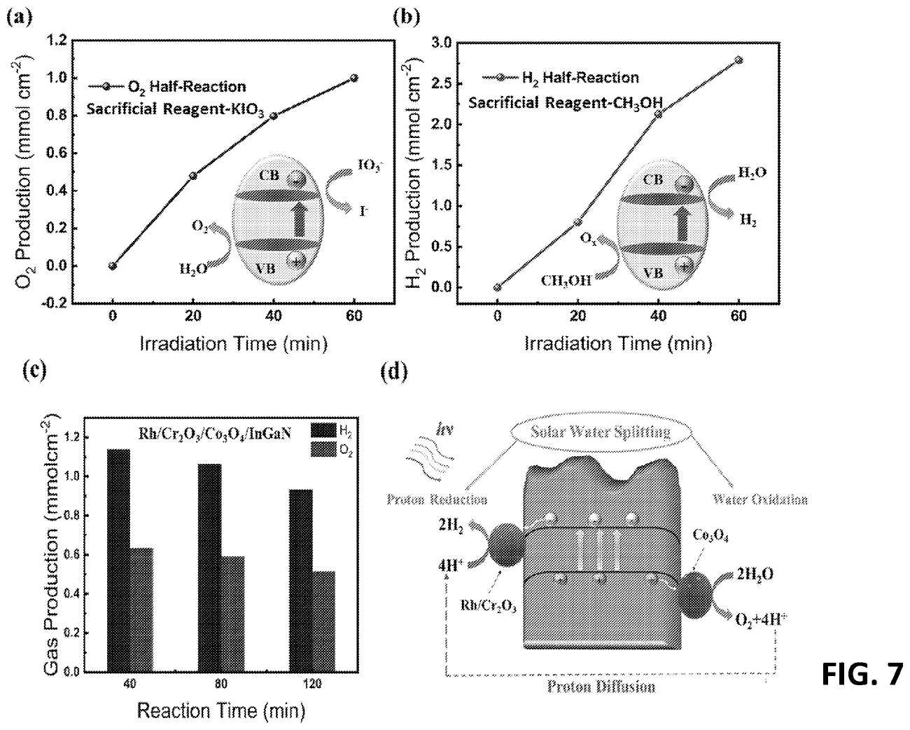

The photocatalytic activity on the p-type doped InGaN micro-network lateral surfaces was investigated by independently carrying out the H₂ and O₂ half-reactions. In case of a photocatalytic reaction taking place in an aqueous medium with the presence of a reducing reagent such as an electron donor or a hole scavenger (i.e., alcohol), the photogenerated holes in the valence band are consumed by the reducing reagent instead of water. This leads to enhanced H₂ evolution. On the other hand, O₂ evolution is enhanced when photogenerated electrons in the conduction band reduce the oxidizing reagents such as electron acceptors or electron scavengers. For the p-InGaN micro-network, CH₃OH was employed as a hole scavenger to perform the H₂ half-reaction and KIO₃ as an electron acceptor to carry out the O₂ half reaction, respectively. The O₂ and H₂ generation over time is depicted in FIG. 7, parts (a) and (b), respectively, with the corresponding reaction processes illustrated in the insets. More than 2.5 mmol cm⁻² of H₂ and 1 mmol cm⁻² of O₂ were generated over one hour using the optimum Mg-doped (T_{Mg}: 210° C.) InGaN micro-network.

Rh, a noble metal, may be used to promote the hydrogen evolution reaction (HER). However, it can also work as catalyst on the backward reaction for the water (H₂O) formation. This can limit its use as a cocatalyst for the overall water splitting process. In order to suppress the back reaction forming H₂O, a transition-metal oxide such as Cr₂O₃ which has no catalytic activity on H₂O formation from H₂ and O₂ is employed. It acts as a coating of diffusion barrier preventing the O₂ from interacting with the Rh surface. In this case, the noble metal (Rh) promotes the hydrogen evolution reaction, whereas the back reaction of water formation over Rh is prevented by Cr₂O₃ shell. On the other hand, Co₃O₄ may be used as an oxygen evolution reaction (OER) cocatalyst.

Additional or alternative catalysts may be used, including, for instance, Pt and MoS₂ for the hydrogen evolution reaction, and, for instance, RuO₂, IrO₂, Co-Pi, FeOOH, and NiOOH for the oxygen evolution reaction.

The overall photocatalytic water splitting was performed on the p-InGaN micro-network photodeposited with the Rh/Cr₂O₃ core-shell and CO₃O₄ nanoparticles.

FIG. 7, part (c), shows the H₂ and O₂ evolution with respect to irradiation time from water splitting under visible light with optimally Mg-doped (T_{Mg}: 210° C.) InGaN micro-network structure. The H₂ to O₂ ratio was approximately 2:1 which indicates a balanced redox reaction of water. Moreover, the pH of the solution (i.e., neutral water) was nearly invariant before and after the reaction which further confirms the stoichiometric evolution of H₂ and O₂. The repeated cycles of overall water splitting reaction proves the stability of p-type InGaN micro-network nanostructure. FIG. 7, part (d), illustrates the redox reaction of the overall photocatalytic water splitting process on the Rh/Cr₂O₃ coreshell and Co₃O₄ nanoparticle decorated InGaN micro-network nanostructures.

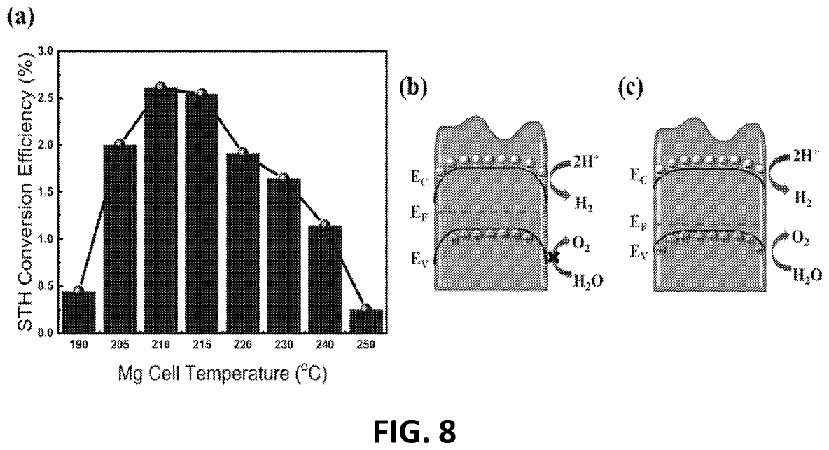

FIG. 8, part (a) shows the solar-to-hydrogen (STH) conversion efficiency values from the overall water splitting of different Mg-doped InGaN micro-network nanostructures. The STH conversion efficiency first increases substantially with increasing T_{Mg} (increase in Mg doping concentration). At an optimum Mg doping level, a solar-to-hydrogen conversion efficiency of about 2.6% was achieved, which is among the highest values reported for direct solar water splitting. Under comparatively low Mg effusion cell temperature, i.e. lower Mg flux, the bulk of the of the InGaN micro-network nanostructure becomes p-type but the Mg dopant incorporation near the surface is low due to Mg desorption from the surface. As such, the surface of the p-InGaN micro-network remains intrinsic or somewhat n-type and so there is a large downward band bending on the surface, as shown on FIG. 8, part (b). With increasing T_{Mg}, the Mg dopant incorporation can be substantially increased near the surface region of the nanostructure. As a result, the near-surface region of the micro-network nanostructure can be changed from intrinsic or n-type to weakly p-type. This significantly reduces the downward band bending and as such the nanostructure surface can achieve near flat band condition in equilibrium with the aqueous medium (FIG. 8, part (c)). This results in the rapid diffusion and efficient extraction of photogenerated electrons and holes towards the micro-network surface which leads to balanced oxidation and reduction reactions. However, further increase in the Mg doping incorporation reduces the surface band bending even further which becomes non-optimal for efficient photogenerated carrier extraction near the micro-network surface in the solution. Moreover, the crystalline quality of the micro-network nanostructure also degrades at high Mg concentration. These factors contribute to the decrease of STH conversion efficiency in the overall water splitting process with increasing Mg doping beyond the optimum level.

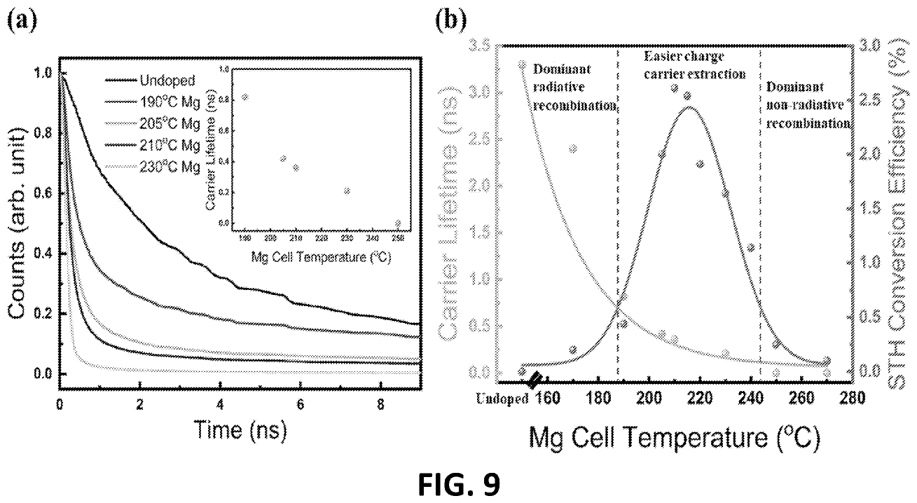

The time-resolved photoluminescence (TRPL) spectra of the InGaN micro-network nanostructure samples for different levels of Mg doping are depicted in FIG. 9, part (a). Standard stretched exponential decay was used for fitting the transients and the corresponding carrier lifetime values are plotted in the inset. A comparatively long carrier lifetime of about 3.5 ns was measured for the undoped InGaN micro-network sample, whereas the lifetime value shows a decreasing trend with increasing Mg cell temperature (higher Mg doping).

The plots in FIG. 9, part (b), show the carrier lifetime and STH conversion efficiency variations with respect to Mg cell temperature. As can be seen in the undoped or low-Mg doped region, the carrier lifetime is very long, whereas the STH conversion efficiency is very low. For the undoped sample, due to the upward band bending, the electrons are essentially confined in the nanostructure conduction band. On the other hand, due to band related bulk defect states, there are many localized holes in the nanostructure. This makes radiative electron-hole recombination more convenient and as such charge carriers cannot diffuse to the micro-network surface easily. Therefore, long carrier lifetime and low STH conversion efficiency values were observed. With Mg-doping incorporation, the InGaN micro-network becomes p-type doped and the energy band achieves near flat band condition on the surface. The lateral dimension of InGaN micro-network nanostructure (e.g., about 40-50 nm) is much smaller than the diffusion length (e.g., about 200-300 nm) of the photo-generated charge carriers. As such, the charge carriers can readily diffuse towards the micro-network surface under the near flat band conditions. This leads to efficient charge carrier extraction and higher STH conversion efficiency. But at the same time, this results in less dominant radiative recombination and thus a decrease in carrier lifetime. On the higher end of Mg doping, band bending near the surface becomes non-optimal and the crystalline quality of the nanostructure degrades. Consequently, the charge carrier extraction becomes inefficient and non-radiative recombination becomes much more dominant. These factors result in the drop in STH conversion efficiency and carrier lifetime, respectively.

The epitaxy, characterization and photocatalytic performance of Mg doped p-type InGaN micro-network nanostructures have been described above. Such p-InGaN micro-network structures are capable of driving spontaneous water splitting and hydrogen production with sunlight as the only energy input. Moreover, the optimum incorporation of Mg-doping enhances the photocatalytic activity by nearly one to two orders of magnitude. The role of Mg doping in significantly enhancing the photocatalytic performance can be explained by the significant impact of Mg doping on the surface band bending and charge carrier extraction. The impact of Mg doping on the carrier lifetime has also been shown. It is found that the carrier lifetime monotonically decreases with increasing Mg doping due to a decrease in radiative-recombination caused by flat band conditions and also dominant non-radiative recombination resulting from degradation in crystalline quality. The above-described InGaN nanostructures may be useful in artificial photosynthesis devices to achieve high efficiency through improved charge carrier dynamics.

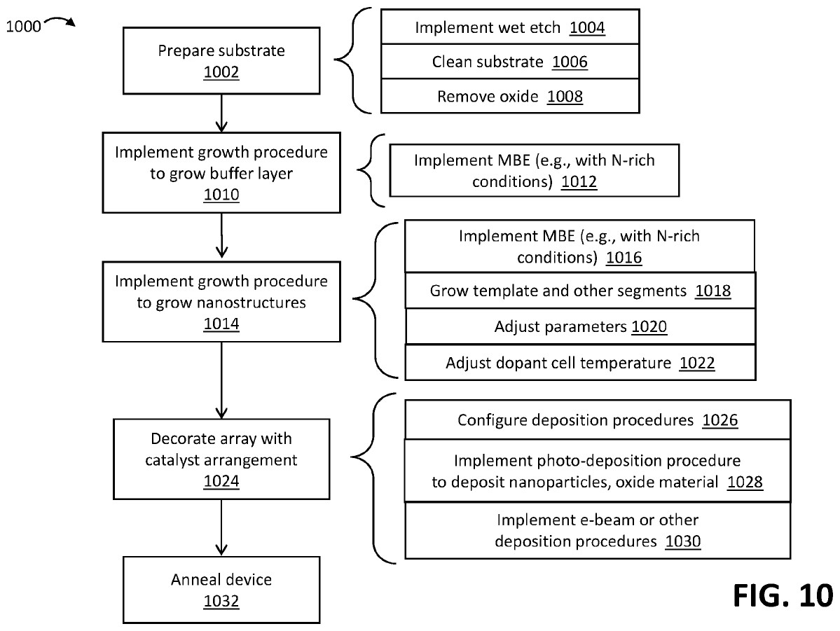

FIG. 10 depicts a method 1000 of fabricating a photocatalytic device for CO₂ reduction in accordance with one example. The method 1000 may be used to manufacture any of the devices described herein or another device. The method 1000 may include additional, fewer, or alternative acts. For instance, the method 1000 may or may not include one or more acts directed to annealing the device (act 1032).

The method 1000 may begin with an act 1002 in which a substrate is prepared or otherwise provided. The substrate may be or be formed from a silicon wafer (e.g., <111> orientation). In one example, a 2-inch Si wafer was used, but other (e.g., larger) size wafers may be used. Other semiconductors and substrates may be used.

In some cases, the act 1002 includes an act 1004 in which a wet or other etch procedure is implemented to define the surface (e.g., nonplanar surface). For example, the etch procedure may be or include a crystallographic etch procedure. In silicon substrate examples, the crystallographic etch procedure may be or otherwise include a KOH etch procedure. In such cases, if the substrate has a <100> orientation, the wet etch procedure establishes that the surface includes a pyramidal textured surface with faces oriented along <111> planes, but additional or alternative facets may be present in some cases.

The act 1002 may include fewer, additional, or alternative acts. For instance, in some examples, the act 1002 includes an act 1006 in which the substrate is cleaned, and an act 1008 in which oxide is removed.

In one example, a prime-grade polished silicon wafer is etched in 80° C. KOH solution (e.g., 1.8% KOH in weight with 20% isopropanol in volume) for 30 minutes to form the micro-textured surface with Si pyramids. After being neutralized in concentrated hydrochloric acid, the substrate surface is cleaned by acetone and/or methanol, and native oxide is removed by 10% hydrofluoric acid.

The method 1000 includes an act 1010 in which a first epitaxial growth procedure to is implemented to grow a buffer layer on a substrate. The growth procedure may be configured such that the buffer layer has a thickness of about 5 nm or less (e.g., about a single monolayer). The buffer layer may be composed of, or otherwise include, AlN, but additional or alternative materials may be used. The act 1010 may include an act 1012 in which an MBE procedure is implemented. In some cases, the MBE growth procedure is configured with N-rich conditions. As described above, the epitaxial growth procedure may have a duration such that the buffer layer includes a plurality of interconnected islands that define voids in the buffer layer.

The method 1000 includes an act 1014 in which a second epitaxial growth procedure is implemented to grow a plurality of nanostructures on the plurality of interconnected islands of the buffer layer. The act 1014 may include an act 1016 in which a molecular beam epitaxy (MBE) is implemented. The MBE procedure may be implemented under nitrogen-rich conditions. The second epitaxial growth procedure may be implemented without a metal catalyst, as described herein.

The act 1014 may include an act 1018 in which segments of each nanostructure are grown. As described above, each heterostructure may include a template layer or segment (e.g., a GaN layer) and one or more segments supported by the template layer. The MBE procedure may be configured in an act 1020 to fabricate the multiple layers or segments of each nanostructure. Various parameters may be adjusted to achieve a selected composition level for the layer. For instance, the substrate temperature may be adjusted. Alternatively or additionally, beam equivalent pressures may be adjusted. In some cases, a dopant cell temperature is adjusted to control the doping (e.g., Mg doping) of the nanostructures in an act 1022.

In the example of FIG. 10, the method 1000 further includes an act 1024 in which the nanostructures are decorated with one or more catalyst arrangements. The catalyst arrangement(s) is/are deposited across the nanostructures. In some cases, the act 1024 includes the deposition of both nanoparticle catalysts (e.g., Rh/Cr₂O₃) for the hydrogen evolution reaction and other nanoparticle catalysts (e.g., Co₃O₄ nanoparticles) for the oxygen evolution reaction. As described herein, one or more of the catalysts of the arrangements may be disposed in, or include, a core-shell configuration (e.g., Rh/Cr₂O₃ core-shell nanoparticles).

The deposition of the nanoparticles may be achieved via implementation of one or more deposition procedures. In the example of FIG. 10, the act 1024 includes an act 1026 in which one or more of the deposition procedures is configured. The configuration may be directed to establishing a ratio of the catalysts.

In the example of FIG. 10, the act 1024 includes an act 1028 in which one or more photo-deposition procedures is implemented. One of the photo-deposition procedures may be configured to form a core-shell catalyst arrangement. Additional or alternative procedures may be used, including, for instance, e-beam evaporation in an act 1030 and/or other physical vapor deposition procedures, such as sputtering, as well as atomic layer deposition procedures.

The method 1000 may include one or more additional acts directed to forming the nanostructures of the device. For instance, in some cases, the method 1000 includes an act 1032 in which the nanostructures of the device are annealed. The parameters of the anneal process may vary.

The order of the above-described acts of the method 1000 may differ from the example shown. For instance, the annealing of the act 1032 may be implemented before or after the deposition of the nanoparticles in the act 1024.

Described above are examples of GaN-based nanostructures that may be used for a broad range of electronic and optoelectronic device applications, as well as for artificial photosynthesis and solar fuel generation. The devices may be fabricated via molecular beam epitaxy to include Mg-doped p-type InGaN micro-network nanostructures with lateral dimensions reaching as small as a few nanometers. Mg doping shows a clear impact on the carrier lifetime and photocatalytic performance of such micro-network nanostructures. The carrier lifetime of InGaN micro-network structures is drastically reduced due to Mg doping incorporation compared to intrinsic structures. Furthermore, these p-type InGaN micro-network nanostructures exhibited remarkable photocatalytic activities for solar water splitting and hydrogen fuel generation. In one example level of Mg doping, a solar-to-hydrogen (STH) conversion efficiency of about 2.6% was achieved in the photocatalytic water splitting process under concentrated sunlight. Furthermore, the examples also demonstrated that variation in Mg doping affected the STH conversion efficiency. The disclosed nanostructures may be used in a variety of high efficiency photocatalytic nanostructure devices and systems.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate;
a buffer layer supported by the substrate; and
a plurality of nanostructures supported by the substrate, each nanostructure of the plurality of nanostructures being shaped as a wall extending outward from the substrate,
wherein the walls of the plurality of nanostructures are interconnected to define a set of voids, each void of the set of voids extending outward from the substrate, and
wherein the buffer layer is disposed between the substrate and each nanostructure of the plurality of nanostructures.

2. The device of claim 1, wherein the buffer layer comprises a plurality of interconnected islands that define voids in the buffer layer.

3. The device of claim 1, wherein the buffer layer comprises AlN.

4. The device of claim 1, wherein the buffer layer has a thickness of about 5 nm or less.

5. The device of claim 1, wherein each nanostructure of the plurality of nanostructures comprises a GaN layer and an InGaN layer supported by the GaN layer.

6. The device of claim 1, wherein each nanostructure of the plurality of nanostructures has a lateral thickness less than about 40 nm.

7. The device of claim 1, wherein each nanostructure of the plurality of nanostructures has a lateral thickness at least an order of magnitude lower than heights of the plurality of nanostructures.

8. The device of claim 1, wherein each nanostructure of the plurality of nanostructures is doped p-type.

9. A method for fabricating a device, the method comprising:
implementing a first epitaxial growth procedure to grow a buffer layer on a substrate, the first epitaxial growth procedure having a duration such that the buffer layer comprises a plurality of interconnected islands that define voids in the buffer layer; and
implementing a second epitaxial growth procedure to grow a plurality of nanostructures on the plurality of interconnected islands of the buffer layer.

10. The method of claim 9, wherein the second epitaxial growth procedure is implemented in a nitrogen-rich environment.

11. The method of claim 9, wherein implementing a second epitaxial growth procedure comprises:
growing a GaN layer on the buffer layer; and
growing an InGaN layer on the GaN layer.

12. The method of claim 9, wherein the second epitaxial growth procedure is implemented without a metal catalyst.

13. The method of claim 9, wherein the first epitaxial growth procedure is configured such that the buffer layer has a thickness of about 5 nm or less.

14. A device comprising:
a substrate;
a buffer layer supported by the substrate; and
a plurality of nanostructures supported by the substrate, each nanostructure of the plurality of nanostructures comprising a III-nitride semiconductor material,
wherein:
the plurality of nanostructures extend outward from the substrate and are vertically aligned;
the buffer layer is disposed between the substrate and each nanostructure of the plurality of nanostructures; and
each nanostructure of the plurality of nanostructures has a lateral dimension sufficiently small so as to promote charge carrier interaction to form excitons.

15. The device of claim 14, wherein the lateral dimension is less than about 40 nm.

16. The device of claim 14, wherein each nanostructure of the plurality of nanostructures is shaped as a wall extending outward from the substrate such that the lateral dimension corresponds with a thickness of the wall.

17. The device of claim 14, wherein each nanostructure of the plurality of nanostructures is doped p-type.

18. A device comprising:
a substrate;
a buffer layer supported by the substrate; and
a plurality of nanostructures supported by the substrate, each nanostructure of the plurality of nanostructures comprising a III-nitride semiconductor material,
wherein:
the plurality of nanostructures extend outward from the substrate and are vertically aligned;
the buffer layer is disposed between the substrate and each nanostructure of the plurality of nanostructures; and
each nanostructure of the plurality of nanostructures has a lateral dimension sufficiently small so as to establish strain relaxation within the III-nitride semiconductor material.

19. The device of claim 18, wherein the lateral dimension is less than about 40 nm.

20. The device of claim 18, wherein each nanostructure of the plurality of nanostructures is shaped as a wall extending outward from the substrate such that the lateral dimension corresponds with a thickness of the wall.

21. The device of claim 18, wherein each nanostructure of the plurality of nanostructures is doped p-type.
